(19) United States
(12) Patent Application Publication
(10) Pub. No.: US 2026/0068248 A1
(43) Pub. Date: Mar. 5, 2026

(54) EMITTER LAYER FORMATION FOR BIPOLAR JUNCTION TRANSISTOR (BJT)

(71) Applicant: TEXAS INSTRUMENTS INCORPORATED, Dallas, TX (US)

(72) Inventors: Jerald Rock, Lisbon, ME (US); Tatsuya Tominari, Plano, TX (US); Hiroshi Yasuda, Plano, TX (US); Mark Taylor, Scarborough, ME (US)

(21) Appl. No.: 18/820,751

(22) Filed: Aug. 30, 2024

(51) Int. Cl. H01L 29/08; H01L 21/02; H01L 29/66; H01L 29/737

(52) U.S. Cl. CPC H10D 62/136; H10D 10/021; H10D 10/821

(57) ABSTRACT

The present disclosure generally relates to semiconductor processing for forming an emitter layer in a bipolar junction transistor (BJT). In an example, a BJT includes a collector, a base on the collector, and an emitter layer on the base. The emitter layer includes a first emitter sub-layer and a second emitter sub-layer over the first emitter sub-layer. The first emitter sub-layer includes boron and carbon. A concentration of carbon is uniform throughout the first emitter sub-layer. The second emitter sub-layer includes boron. A concentration of boron in the second emitter sub-layer is greater than a concentration of boron in the first emitter sub-layer.

### BACKGROUND

Integrated circuits may include bipolar junction transistors (BJTs). BJTs may be desirable for their high gain characteristics to satisfy high performance and high current drive needs. Scaling of devices in an integrated circuit to smaller nodes typically requires novel approaches to semiconductor processing for fabricating those devices.

### SUMMARY

An example described herein is a bipolar junction transistor. The bipolar junction transistor includes a collector, a base on the collector, and an emitter layer on the base. The emitter layer includes a first emitter sub-layer and a second emitter sub-layer over the first emitter sub-layer. The first emitter sub-layer includes boron and carbon. A concentration of carbon is uniform throughout the first emitter sub-layer. The second emitter sub-layer includes boron. A concentration of boron in the second emitter sub-layer is greater than a concentration of boron in the first emitter sub-layer.

Another example is a method. A bipolar junction transistor is formed. The bipolar junction transistor includes a collector, a base on the collector, and an emitter layer on the base. Forming the bipolar junction transistor includes forming the emitter layer. Forming the emitter layer includes forming a first emitter sub-layer and forming a second emitter sub-layer over the first emitter sub-layer. Forming the second emitter sub-layer includes in situ doping, at a temperature, the second emitter sub-layer with boron to a concentration of boron equal to or greater than 5×10²⁰ cm⁻³. The temperature being 475° C. or less.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a simplified structure of a bipolar junction transistor (BJT) according to some examples.

FIG. 2 is a flowchart of a method of manufacturing the BJT of FIG. 1 according to some examples.

FIGS. 3 through 22 are respective cross-sectional views of a semiconductor device in intermediate stages of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing for forming an emitter layer in a bipolar junction transistor (BJT). Some examples include a BJT that includes a collector, a base on the collector, and an emitter layer on the base. The emitter layer includes a first emitter sub-layer and a second emitter sub-layer over the first emitter sub-layer. The first emitter sub-layer includes boron and carbon. A concentration of carbon is uniform throughout the first emitter sub-layer. The second emitter sub-layer includes boron. A concentration of boron in the second emitter sub-layer is greater than a concentration of boron in the first emitter sub-layer. In some examples, the second emitter sub-layer may be formed by epitaxially growing the second emitter sub-layer at a temperature of 475° C. or less with in situ doping boron to a concentration equal to or greater than 5×10²⁰ cm⁻³. Among other things, a lower thermal budget may be implemented to form such a device, which may reduce diffusion of dopants. Implementing relatively higher cost processing tools may be avoided in this manner. Improved emitter resistance may also be achieved. Other benefits and advantages may be achieved.

Various examples are described subsequently. Although the specific examples may illustrate various aspects of the above generally described features, examples may incorporate any combination of the above generally described features (which are described in more detail in examples below).

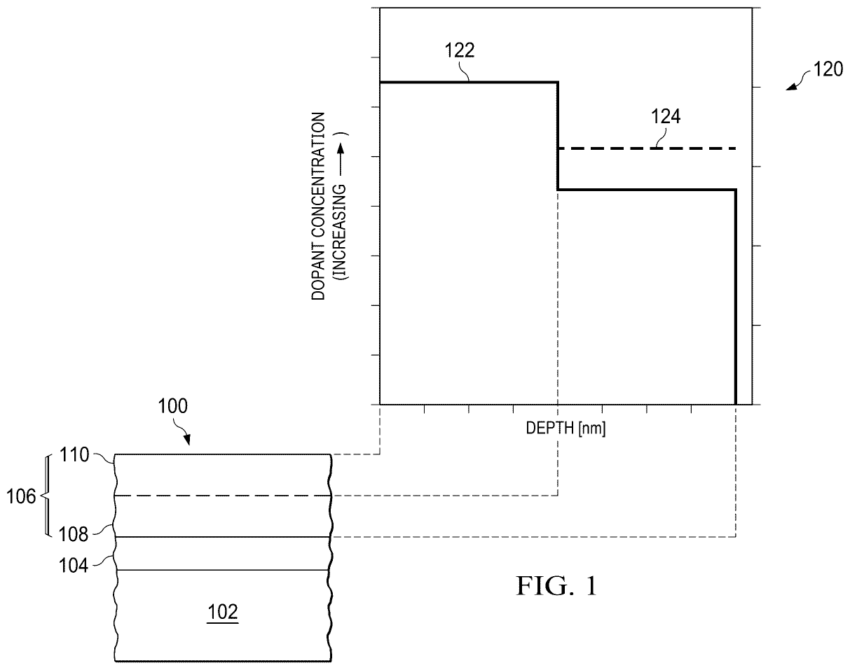

FIG. 1 is a simplified structure of a BJT 100 according to some examples. The BJT 100 in this example is a PNP BJT. The BJT 100 includes a collector 102, a base 104, and an emitter layer 106. The emitter layer 106 includes a first emitter sub-layer 108 and a second emitter sub-layer 110. The base 104 is on and over the collector 102, and the emitter layer 106 is on and over the base 104. The first emitter sub-layer 108 is on and over the base 104, and the second emitter sub-layer 110 is on and over the first emitter sub-layer 108. The collector 102 and the emitter layer 106 are or include respective p-doped regions or layers, and the base 104 is or includes an n-doped region or layer.

The collector 102 and the base 104 may each be, for example, a region in a semiconductor substrate implanted to be or include a p-doped and n-doped region, respectively, and/or an epitaxial layer in situ doped and/or implanted to be or include a p-doped and n-doped layer (or sub-layer), respectively.

As detailed subsequently, the emitter layer 106 (including the emitter sub-layers 108, 110) is epitaxially grown (e.g., selectively or non-selectively) on the base 104. The emitter layer 106 (e.g., each of the emitter sub-layers 108, 110) is or includes a semiconductor material, which may be or include a monocrystalline semiconductor material and/or a polycrystalline semiconductor material. For example, if the first emitter sub-layer 108 or the second emitter sub-layer 110 is epitaxially grown on a monocrystalline surface, the sub-layer may be monocrystalline, or if the first emitter sub-layer 108 or the second emitter sub-layer 110 is epitaxially grown on a polycrystalline or amorphous surface, the sub-layer may be polycrystalline. In some examples, any and/or each of the emitter sub-layers 108, 110 may include a monocrystalline portion epitaxially grown on a monocrystalline surface and a polycrystalline portion epitaxially grown on a polycrystalline or amorphous surface. The semiconductor material may be any appropriate semiconductor material, such as silicon.

The first emitter sub-layer 108 and the second emitter sub-layer 110 are each p-doped with a p-type dopant, such as boron (B). FIG. 1 also shows a doping profile 120 of the emitter layer 106. The doping profile 120 shows a p-type dopant profile 122. As shown by the p-type dopant profile 122, a concentration of the p-type dopant (e.g., boron) in the second emitter sub-layer 110 is greater than a concentration of the p-type dopant (e.g., boron) in the first emitter sub-layer 108. The respective concentrations of the p-type dopant may be substantially uniform throughout respective thicknesses of the first emitter sub-layer 108 and the second emitter sub-layer 110. In some examples, a concentration of the p-type dopant in the first emitter sub-layer 108 is in a range from 1×10¹⁹ cm⁻³ to 5×10²⁰ cm⁻³, and a concentration of the p-type dopant in the second emitter sub-layer 110 is equal to or greater than 5×10²⁰ cm⁻³, such as equal to or greater than 1×10²¹ cm⁻³. More specifically, in some examples, a concentration of the p-type dopant in the first emitter sub-layer 108 may be 5×10¹⁹ cm⁻³, and a concentration of the p-type dopant in the second emitter sub-layer 110 may be 1×10²¹ cm⁻³. The first emitter sub-layer 108 may be moderately doped for proper functionality of the BJT 100, while the second emitter sub-layer 110 may be heavily doped to achieve a low contact resistance.

The first emitter sub-layer 108 is also doped with carbon, and in some examples, the second emitter sub-layer 110 may or may not be doped with carbon. The doping profile 120 further shows a carbon profile 124. As shown by the carbon profile 124, a concentration of carbon in the first emitter sub-layer 108 is greater than a concentration of carbon in the second emitter sub-layer 110. The respective concentrations of carbon may be substantially uniform throughout respective thicknesses of the first emitter sub-layer 108 and the second emitter sub-layer 110. In some examples, a concentration of carbon in the first emitter sub-layer 108 corresponds to equal to or greater than 0.2 atomic percent (at. %), such as in a range from 0.2 at. % to 1 at. %, of the first emitter sub-layer 108, and a concentration of carbon in the second emitter sub-layer 110 corresponds to equal to or less than 0.2 at. % of the second emitter sub-layer 110. More specifically, in some examples, a concentration of carbon in the first emitter sub-layer 108 may correspond to 0.2 at. % of the first emitter sub-layer 108, and the second emitter sub-layer 110 does not include or is exclusive of carbon (e.g., a concentration of 0 at. %). For clarity, the concentrations shown by the p-type dopant profile 122 do not have a relation to (e.g., greater or less than) the concentration shown by the carbon profile 124.

In some examples, a thickness of the emitter layer 106 may be in a range from 30 nm to 150 nm. A thickness of the first emitter sub-layer 108 may be in a range from 15 nm to 50 nm, such as 40 nm, and a thickness of the second emitter sub-layer 110 may be in a range from 15 nm to 100 nm, such as 40 nm.

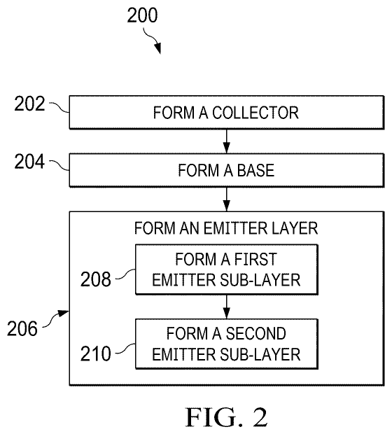

FIG. 2 is a flowchart of a method 200 of manufacturing the BJT 100 of FIG. 1 according to some examples. The method 200 includes forming a collector 102 at block 202, forming a base 104 on the collector 102 at block 204, and forming an emitter layer 106 on or over the base 104 at block 206. Forming the emitter layer 106 at block 206 includes forming a first emitter sub-layer 108 on or over the base 104 at block 208 and forming a second emitter sub-layer 110 on or over the first emitter sub-layer 108 at block 210.

Forming the collector 102 at block 202 may include implanting p-type dopants (e.g., boron (B)) into a semiconductor material, such as a semiconductor substrate, and/or depositing, such as by epitaxial growth, a semiconductor layer on or over a semiconductor substrate where the deposition includes in situ doping the semiconductor layer with a p-type dopant. Hence, the collector 102 may be or include a p-type doped region in a semiconductor material (e.g., in a semiconductor substrate) and/or a p-type doped semiconductor layer (e.g., over or on a semiconductor substrate).

Forming the base 104 on the collector 102 at block 204 may include implanting n-type dopants (e.g., phosphorus (P) and/or arsenic (As)) into a semiconductor material, such as a semiconductor substrate, and/or depositing, such as by epitaxial growth, a semiconductor layer on or over a semiconductor substrate where the deposition includes in situ doping the semiconductor layer with an n-type dopant. Hence, the base 104 may be or include an n-type doped region in a semiconductor material (e.g., in a semiconductor substrate) and/or an n-type doped semiconductor layer (e.g., over or on a semiconductor substrate). For example, the collector 102 may include a p-doped region in a semiconductor substrate, and the base 104 may include an n-doped region in the semiconductor substrate. As another example, the collector 102 may include a p-doped epitaxial layer over a semiconductor substrate, and the base 104 may include an n-doped epitaxial layer on or over the p-doped epitaxial layer of the collector 102. As a further example, the collector 102 may include a p-doped region in a semiconductor substrate, and the base 104 may include an n-doped epitaxial layer on or over p-doped region in the semiconductor substrate of the collector 102.

Forming the first emitter sub-layer 108 at block 208 includes epitaxially growing the first emitter sub-layer 108. The epitaxial growth process may be a chemical vapor deposition (CVD) process, such as low pressure CVD (LPCVD), reduced pressure CVD (RPCVD), metal organic CVD (MOCVD), or the like. The first emitter sub-layer 108 is in situ doped with a p-type dopant (e.g., boron (B)) and carbon to concentrations as described above with respect to FIG. 1. Epitaxially growing the first emitter sub-layer 108 includes flowing a gas mixture in a process chamber of the epitaxial growth. The gas mixture includes nitrogen (N₂) gas, silane (SiH₄) gas, diborane (B₂H₆) gas, and a carbon source gas. In some examples, the carbon source gas is or includes monomethylsilane (MMS, CH₃SiH₃) gas. In some examples, the gas mixture used to epitaxially grow the first emitter sub-layer 108 does not include hydrogen (H₂) gas and does not include a gas that includes one or more chlorine atoms. In some examples, the epitaxial growth process includes, in flowing in the gas mixture, a flow rate of the nitrogen (N₂) gas in a range from 10 standard liter per minute (slm) to 15 slm; a flow rate of the silane (SiH₄) gas in a range from 150 standard cubic centimeter per minute (sccm) to 250 sccm; a flow rate of the diborane (B₂H₆) gas that results in a target concentration of diborane (B₂H₆) in the gas mixture; and a flow rate of the carbon source gas (e.g., MMS (CH₃SiH₃) gas at a 1% concentration diluted in hydrogen (H₂) gas) in a range from 10 sccm to 90 sccm. In some examples, a concentration of diborane (B₂H₆) in the gas mixture is in a range from 100 parts per billion (ppb) to 400 ppb. In some examples, a temperature of the epitaxial growth process for epitaxially growing the first emitter sub-layer 108 is greater than or equal to 500° C., such as in a range from 500° C. to 600° C., and more particularly, such as 550° C.

Forming the second emitter sub-layer 110 at block 210 includes epitaxially growing the second emitter sub-layer 110. The epitaxial growth process may be a CVD process, such as LPCVD, RPCVD, MOCVD, or the like. The second emitter sub-layer 110 is in situ doped with a p-type dopant (e.g., boron (B)) as described above with respect to FIG. 1. In some examples, the second emitter sub-layer 110 is not in situ doped with carbon, although the second emitter sub-layer 110 may be in situ doped with carbon in other examples. Epitaxially growing the second emitter sub-layer 110 includes flowing a gas mixture in a process chamber of the epitaxial growth, which may be a same process chamber of the epitaxial growth of the first emitter sub-layer 108. The gas mixture includes nitrogen (N₂) gas, silane (SiH₄) gas, and diborane (B₂H₆) gas. In some examples, the gas mixture used to epitaxially grow the second emitter sub-layer 110 does not include hydrogen (H₂) gas and does not include a gas that includes one or more chlorine atoms. In some examples, the epitaxial growth process includes, flowing in the gas mixture, a flow rate of the nitrogen (N₂) gas in a range from 10 slm to 15 slm; a flow rate of the silane (SiH₄) gas in a range from 100 sccm to 200 sccm; and a flow rate of the diborane (B₂H₆) gas that results in a target concentration of diborane (B₂H₆) in the gas mixture. In some examples, a concentration of diborane (B₂H₆) in the gas mixture is less than 9,500 parts per billion (ppb), such as in a range from 3,000 ppb to 9,500 ppb. In some examples, a temperature of the epitaxial growth process for epitaxially growing the second emitter sub-layer 110 is equal to or less than 475° C., such as in a range from 425° C. to 475° C., and more particularly, such as 450° C. The temperature at which the first emitter sub-layer 108 is epitaxially grown (e.g., 550° C.) is greater than, such as 100° C. or more greater than, the temperature at which the second emitter sub-layer 110 is epitaxially grown (e.g., 450° C.).

In some examples, before forming the emitter layer 106 (including forming the emitter sub-layers 108, 110), a bake process may be performed on the BJT structure including the collector 102 and base 104. The bake process may be performed in a hydrogen (H₂) environment. For example, a flow rate of hydrogen (H₂) gas for the bake process may be in a range from 10 slm to 20 slm. The bake process may be performed at a temperature in a range from 825° C. to 900° C., such as at 850° C. for a duration in a range from 1 minutes to 3 minutes. In some examples, before forming the emitter layer 106 (including forming the emitter sub-layers 108, 110), a clean process may be performed on the BJT structure including the collector 102 and base 104. The clean process may include performing a plasma clean, such as a nitrogen trifluoride (NF₃) plasma.

It is believed that previous processes to deposit an emitter layer could not achieve, by in situ doping, a boron dopant concentration of 5×10²⁰ cm⁻³ or greater (e.g., 1×10²¹ cm⁻³ or greater) with a temperature of the deposition being 475° C. or lower. It is believed that, among other things, because previous processes used hydrogen (H₂) gas as a carrier gas and used dichlorosilane (DCS, H₂SiCl₂) gas as a silicon source gas, hydrogen (from the hydrogen (H₂) gas) and chlorine (from the DCS (H₂SiCl₂) gas) would terminate the upper surface of the emitter layer during epitaxial growth of the emitter layer at a temperature of 475° C. or lower such that boron would be inhibited from being adsorbed into the emitter layer. This inhibition would prevent the emitter layer from reaching a boron dopant concentration of 5×10²⁰ cm⁻³ or greater (e.g., 1×10²¹ cm⁻³ or greater).

In experiments, it was observed that changing a silicon source gas for epitaxially growing boron-doped silicon from DCS (H₂SiCl₂) gas to silane (SiH₄) gas increased the boron dopant concentration, assuming all other process parameters were constant between the processes. Similarly, it was observed that changing a carrier gas for epitaxially growing boron-doped silicon from hydrogen (H₂) gas to nitrogen (N₂) gas increased the boron dopant concentration, assuming all other process parameters were constant between the processes, including using silane (SiH₄) gas as the silicon source gas. Hence, according to some examples of the present disclosure, hydrogen (H₂) gas is not used in an epitaxial growth of, e.g., the second emitter sub-layer 110. Similarly, according to some examples of the present disclosure, a silicon source gas that includes one or more chlorine atoms (e.g., DCS (H₂SiCl₂) gas) is not used in an epitaxial growth of, e.g., the second emitter sub-layer 110.

Experiments further showed that increasing a concentration of diborane (B₂H₆) gas in the gas mixture of the epitaxial growth could achieve higher boron dopant concentrations at lower temperatures. In these experiments, a flow rate of silane (SiH₄) gas was constant between experiments and was 200 sccm, and a flow rate of nitrogen (N₂) gas was also constant between experiments. For example, experiments in which the diborane (B₂H₆) gas in the gas mixture was 3,194 ppb realized boron dopant concentrations of less than 3×10²⁰ cm⁻³ for epitaxial processes at temperatures ranging from 450° C. to 550° C. Experiments in which the diborane (B₂H₆) gas in the gas mixture was 6,347 ppb realized boron dopant concentrations between approximately 3×10²⁰ cm³ and 7×10²⁰ cm⁻³ for epitaxial processes at 450° C. and boron dopant concentrations less than approximately 3×10²⁰ cm⁻³ for epitaxial processes with temperatures ranging from 500° C. to 550° C. However, experiments in which the diborane (B₂H₆) gas in the gas mixture was 9,460 ppb realized a boron dopant concentration of approximately 1.3×10²¹ cm⁻³ for an epitaxial process at 450° C. and boron dopant concentrations at or less than approximately 3×10²⁰ cm⁻³ for epitaxial processes with temperatures ranging from 500° C. to 550° C. Also, for the experiment in which the diborane (B₂H₆) gas in the gas mixture was 9,460 ppb and the temperature was 450° C., the resulting silicon layer was observed to be monocrystalline, which indicated that monocrystalline silicon may be achieved by such epitaxial growth.

Experiments were also conducted varying a flow rate of silane (SiH₄) gas to observe the effect on boron dopant concentration and growth rate. Generally, increasing the flow rate of silane (SiH₄) gas was observed to decrease the boron dopant concentration and to increase the growth rate. The epitaxial processes for the experiments used a flow rate of diborane (B₂H₆) gas of 180 sccm and was performed at a temperature of 450° C. Flow rates of silane (SiH₄) gas that were between 90 sccm and approximately 123 sccm were observed to result in a boron dopant concentration of 1×10²¹ cm⁻³ or greater and to result in a growth rate from approximately 21 nm/minute to approximately 26.6 nm/minute. A flow rate of silane (SiH₄) gas of approximately 123 sccm was observed to result in a boron dopant concentration of approximately 1×10²¹ cm⁻³ with a growth rate of approximately 26.6 nm/minute. Flow rates of silane (SiH₄) gas that were between approximately 123 sccm and approximately 178 sccm were observed to result in a boron dopant concentration between approximately 5×10²⁰ cm⁻³ and approximately 1×10²¹ cm⁻³ and to result in a growth rate from approximately 26.6 nm/minute to approximately 35.7 nm/minute. A flow rate of silane (SiH₄) gas of approximately 178 sccm was observed to result in a boron dopant concentration of approximately 5×10²⁰ cm⁻³ with a growth rate of approximately 35.7 nm/minute.

Based on these described experiments, the processing described with respect to FIGS. 1 and 2 was developed. Based on the described processing, it was observed that epitaxial growth of an emitter sub-layer may be performed at lower temperatures, such as less than or equal to 475° C. (e.g., 450° C.), and a boron dopant concentration of 5×10²⁰ cm⁻³ or more (e.g., 1×10²¹ cm⁻³ or more) may be achieved.

The epitaxial process for forming the second emitter sub-layer 110 may improve thermal budgets for forming the BJT 100. The reduced temperature of the epitaxial process may reduce diffusion of dopants in other layers or sub-layers. For example, the reduced temperature for epitaxially growing the second emitter sub-layer 110 may reduce diffusion of p-type dopants (e.g., boron (B)) in the first emitter sub-layer 108, which may diffuse into the base 104. Reducing such diffusion may prevent improper doping of regions or layers from occurring.

Electrical tests were performed on BJTs formed by processing described above with respect to FIGS. 1 and 2. In the example BJTs, boron dopant concentration was increased, and emitter resistance (Rₑ) was reduced relative to BJTs formed by previous processing. Further, frequency responses of the example BJTs were improved due, at least in part, to the reduced emitter resistance (Rₑ).

Additionally, the processing described above to form an emitter layer 106 may be performed using mature, relatively low cost processing tools. Using such tools may avoid a need to use relatively high cost processing tools that may have been implemented to achieve layers with dopant concentrations described herein. In some instances, the described example process may provide for a low boron concentration epitaxial process for a high voltage application without any hardware change (e.g., such as a high concentration diborane (B₂H₆) tool configuration addition) resulting lower tool cost.

In some examples, the second emitter sub-layer 110 may be in situ doped with carbon, as indicated above. For example, MMS (CH₃SiH₃) gas may be incorporated into the gas mixture used for the epitaxial growth of the second emitter sub-layer 110. In experiments, a flow rate of MMS (CH₃SiH₃) gas (e.g., MMS (CH₃SiH₃) gas at a 1% concentration diluted in hydrogen (H₂) gas) showed high linearity with the carbon dopant concentration in the resulting second emitter sub-layer 110. For example, flowing MMS (CH₃SiH₃) gas at a flow rate of 10 sccm achieved a carbon dopant concentration of 0.2 at. %; flowing MMS (CH₃SiH₃) gas at a flow rate of 25 sccm achieved a carbon dopant concentration of 0.4 at. %; flowing MMS (CH₃SiH₃) gas at a flow rate of 50 sccm achieved a carbon dopant concentration of 0.65 at. %; and flowing MMS (CH₃SiH₃) gas at a flow rate of 90 sccm achieved a carbon dopant concentration of 1.1 at. %.

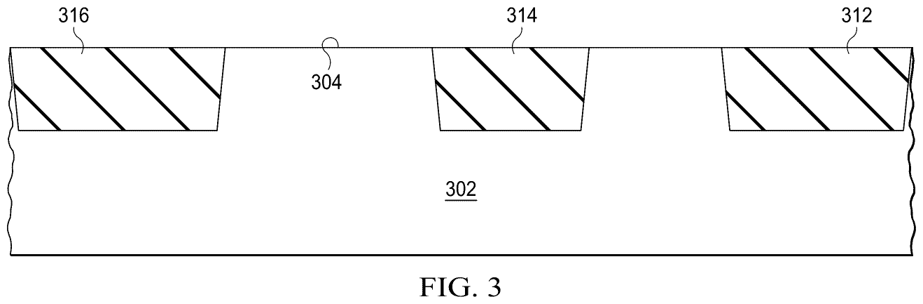

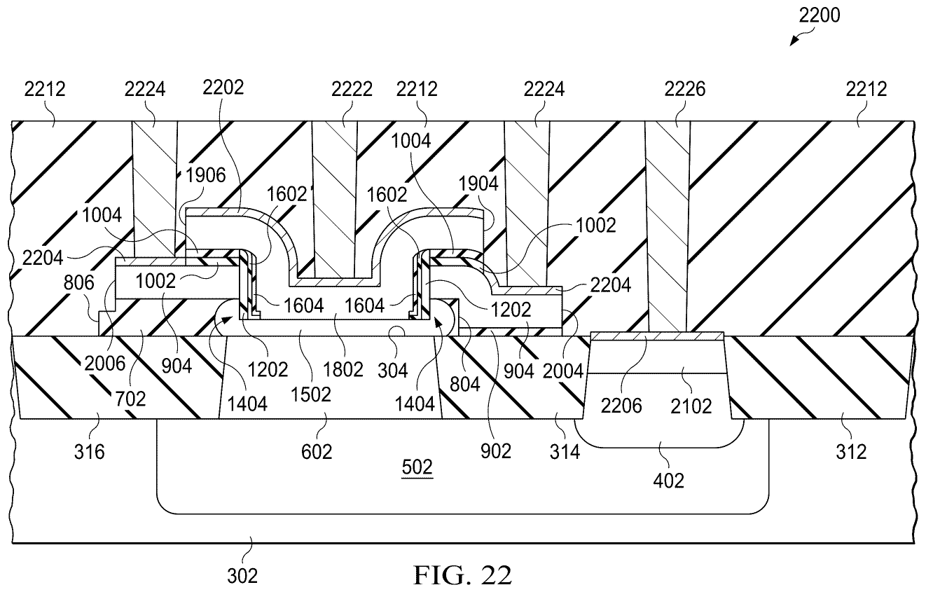

FIGS. 3 through 22 are respective cross-sectional views of a semiconductor device in intermediate stages of manufacturing according to some examples. The method illustrated in these figures forms the semiconductor device 2200 (e.g., a BJT) of FIG. 22. The manufacturing method described above with respect to FIGS. 1 and 2 is implemented in the manufacturing illustrated in FIGS. 3 through 22, as referenced subsequently.

Referring to FIG. 3, a semiconductor substrate 302 is provided. The semiconductor substrate 302 may be or include a bulk semiconductor substrate, a semiconductor-on-insulator (SOI) substrate, or any other appropriate substrate. The semiconductor substrate 302 may also include a support (or handle) substrate and an epitaxial layer epitaxially grown on the support substrate. In some examples, the semiconductor substrate 302 is or includes a silicon substrate (which may be singulated from a bulk silicon wafer at the conclusion of semiconductor processing). In further examples, the semiconductor substrate 302 includes a silicon substrate with an epitaxial silicon layer grown thereon. The semiconductor substrate 302 is or includes a semiconductor material in and/or on which devices, such as a BJT (as described subsequently), are formed. In some examples, the semiconductor material is or includes silicon (Si), silicon germanium (SiGe), gallium arsenide (GaAs), gallium nitride (GaN), the like, or a combination thereof. The semiconductor substrate 302 has an upper surface 304 in and/or on which devices (e.g., the BJT) are formed. In the illustrated example, the semiconductor material of the semiconductor substrate 302 is p-type doped with a p-type dopant. In some examples, the semiconductor substrate 302 is p-type doped with a p-type dopant (e.g., boron (B)) with a concentration in a range from 1×10¹⁴ cm⁻³ to 1×10¹⁵ cm⁻³. Another dopant type and/or other doping concentrations may be implemented.

Isolation structures 312, 314, 316 are formed in the semiconductor substrate 302. In the illustrated example, the isolation structures 312, 314, 316 are shallow trench isolation structures (STIs) extending from the upper surface 304 of the semiconductor substrate 302 into the semiconductor substrate 302. As illustrated, the isolation structures 312, 314, 316 have upper surfaces co-planar with the upper surface 304 of the semiconductor substrate 302, and in other examples, the upper surfaces of the isolation structures 312, 314, 316 may be above, below, and/or co-planar with the upper surface 304 of the semiconductor substrate 302. The isolation structures 312, 314, 316 may include, for example, a liner layer, such as including silicon oxide or silicon nitride, conformally along surfaces of a respective trench in the semiconductor substrate 302 and a fill isolation material, such as silicon oxide, over and on the liner layer.

To form the isolation structures 312, 314, 316, trenches are formed in the semiconductor substrate 302. A hardmask layer may be formed over the semiconductor substrate 302. In some examples, the hardmask layer may be or include silicon nitride, which may be deposited by CVD. The hardmask layer may then be patterned, such as by using photolithography and an etching process (e.g., reactive ion etch (RIE)). The trenches may be etched, such as by RIE, in the semiconductor substrate 302 using the patterned hardmask layer as a mask. The liner layer may then be conformally deposited in the recesses or trenches and over the patterned hardmask layer, such as by plasma enhanced CVD (PECVD) or formed on exposed surfaces of the recesses or trenches (e.g., by an oxidation process), and the fill isolation material may be deposited over the liner layer, such as by high aspect ratio CVD (HAR-CVD), flowable CVD (FCVD), or the like. Excess fill isolation material and liner layer may be removed from over the hardmask layer by a planarization process, such as a chemical mechanical polish (CMP). The hardmask layer may then be removed by an etch selective to the hardmask layer, which may be a wet etch process. In other examples, the isolation structures 312, 314, 316 may be field oxide structures, such as local oxidation of silicon (LOCOS) structures, at the upper surface 304 of the semiconductor substrate 302, which may be formed using a LOCOS process.

The isolation structures 312, 316 laterally define an area (e.g., an active area) of the upper surface 304 of the semiconductor substrate 302 on which the BJT is to be formed. The isolation structures 312, 316 together laterally encircle or encompass the active area of the upper surface 304 of the semiconductor substrate 302 on which the BJT is to be formed. As indicated subsequently, an active portion (e.g., a base layer) of the BJT extends laterally beyond the active area of the upper surface 304 of the semiconductor substrate 302 on which the BJT is formed and over the isolation structure 316.

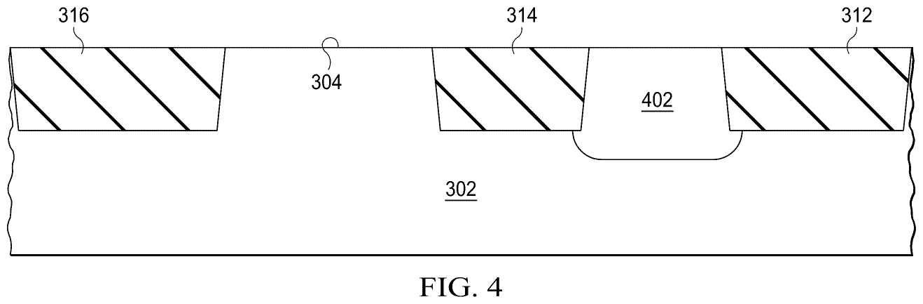

Referring to FIG. 4, a first p-type sub-collector diffusion well 402 is formed in the semiconductor substrate 302. The first p-type sub-collector diffusion well 402 is formed in the semiconductor substrate 302 extending from the upper surface 304 of the semiconductor substrate 302 to a depth in the semiconductor substrate 302 below bottom surfaces of the isolation structures 312, 314. The first p-type sub-collector diffusion well 402 is laterally between the isolation structures 312, 314. An implantation is performed to form the first p-type sub-collector diffusion well 402. The first p-type sub-collector diffusion well 402 may be formed by masking (e.g., by a photoresist using photolithography) areas of the semiconductor substrate 302 where a well is not to be formed and implanting a p-type dopant into the semiconductor substrate 302 in an exposed portion of the semiconductor substrate 302 corresponding to the first p-type sub-collector diffusion well 402. A concentration of the p-type dopant of the first p-type sub-collector diffusion well 402 is greater than the concentration of the p-type dopant of the p-type doped semiconductor substrate 302. In some examples, the first p-type sub-collector diffusion well 402 is doped with a p-type dopant with a concentration in a range from 1×10¹⁸ cm⁻³ to 1×10²⁰ cm⁻³. Other doping concentrations may be implemented.

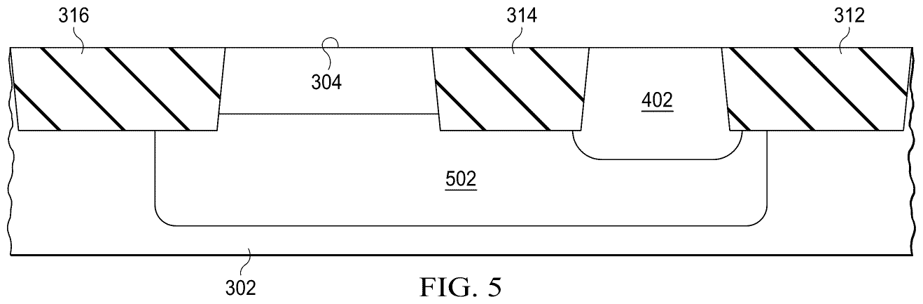

Referring to FIG. 5, a p-type buried layer 502 is formed in the semiconductor substrate 302. The p-type buried layer 502 is formed in the semiconductor substrate 302 generally below the isolation structures 312, 314, 316. The p-type buried layer 502 extends laterally from below the isolation structure 312, under the isolation structure 314, and to under the isolation structure 316. As used herein, a buried layer is a layer in a semiconductor substrate (e.g., the semiconductor substrate 302) and with characteristics, such as conductivity type or dopant concentration, that is spaced apart from a top surface of the semiconductor substrate (e.g., the upper surface 304 of the semiconductor substrate 302) by a spacing layer or material that has a significantly different characteristic, such as different conductivity type or different dopant concentration. The first p-type sub-collector diffusion well 402 extends into the p-type buried layer 502. An implantation is performed to form the p-type buried layer 502. The p-type buried layer 502 may be formed by masking (e.g., by a photoresist using photolithography) areas of the semiconductor substrate 302 where a buried layer is not to be formed and implanting a p-type dopant into the semiconductor substrate 302 in an exposed portion of the semiconductor substrate 302 corresponding to the p-type buried layer 502. A concentration of the p-type dopant of the p-type buried layer 502 is greater than the concentration of the p-type dopant of the p-type doped semiconductor substrate 302 and may be approximately equal to the concentration of the p-type dopant of the first p-type sub-collector diffusion well 402. In some examples, the p-type buried layer 502 is doped with a p-type dopant with a concentration in a range from 1×10¹⁸ cm⁻³ to 1×10²⁰ cm⁻³. Other doping concentrations may be implemented.

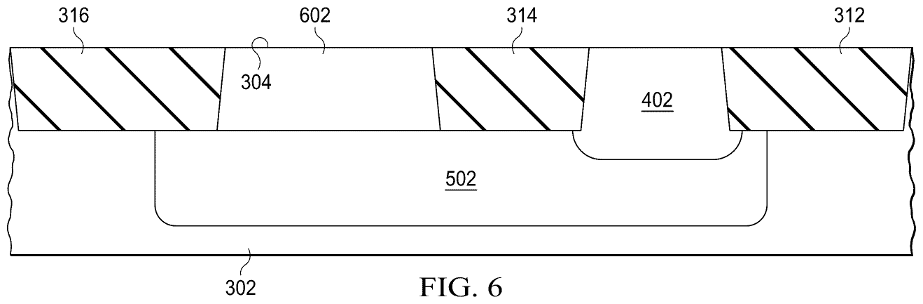

Referring to FIG. 6, a second p-type sub-collector diffusion well 602 is formed in the semiconductor substrate 302. The second p-type sub-collector diffusion well 602 is formed in the semiconductor substrate 302 extending from the upper surface 304 of the semiconductor substrate 302 to a depth in the semiconductor substrate 302 generally at or below bottom surfaces of the isolation structures 314, 316. The second p-type sub-collector diffusion well 602 extends to or into the p-type buried layer 502. The second p-type sub-collector diffusion well 602 is laterally between the isolation structures 314, 316. An implantation is performed to form the second p-type sub-collector diffusion well 602. The second p-type sub-collector diffusion well 602 may be formed by masking (e.g., by a photoresist using photolithography) areas of the semiconductor substrate 302 where a well is not to be formed and implanting a p-type dopant into the semiconductor substrate 302 in an exposed portion of the semiconductor substrate 302 corresponding to the second p-type sub-collector diffusion well 602. A concentration of the p-type dopant of the second p-type sub-collector diffusion well 602 is greater than the concentration of the p-type dopant of the p-type doped semiconductor substrate 302 and is equal to or less than the concentration of the p-type dopant of the p-type buried layer 502. In some examples, the second p-type sub-collector diffusion well 602 is doped with a p-type dopant with a concentration in a range from 1×10¹⁸ cm⁻³ to 1×10¹⁹ cm⁻³. Other doping concentrations may be implemented.

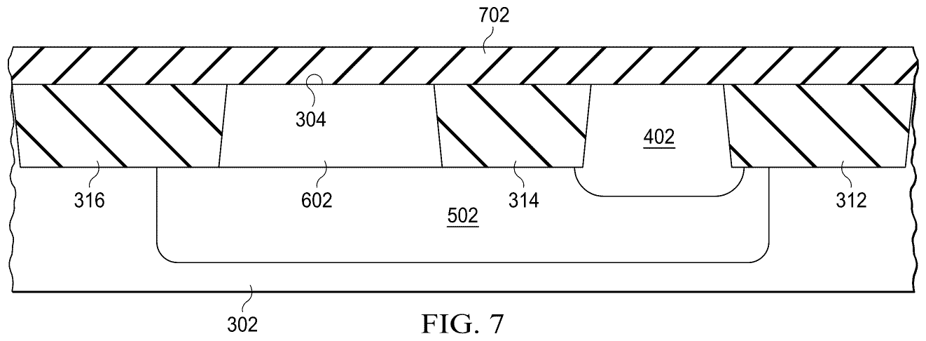

Referring to FIG. 7, a pedestal dielectric layer 702 is formed over the semiconductor substrate 302. The pedestal dielectric layer 702 is deposited over the upper surface 304 of the semiconductor substrate 302 and the isolation structures 312, 314, 316. In some examples, the pedestal dielectric layer 702 is or includes silicon oxide (e.g., a tetraethyl orthosilicate (TEOS) oxide) deposited by CVD, although other dielectric materials and/or other deposition processes may be used in other examples.

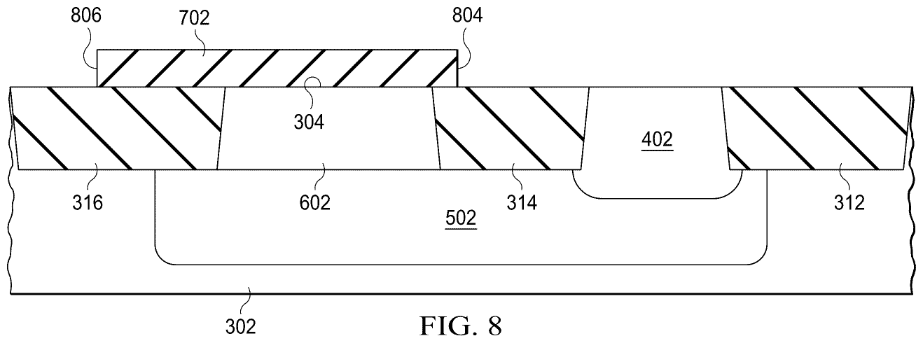

Referring to FIG. 8, the pedestal dielectric layer 702 is patterned. The pedestal dielectric layer 702 is patterned to remain over the second p-type sub-collector diffusion well 602 in the semiconductor substrate 302 and extending at least partially over the isolation structures 314, 316. The pedestal dielectric layer 702 is patterned to have a sidewall 804 over the isolation structure 314 and a sidewall 806 over the isolation structure 316. The pedestal dielectric layer 702 is patterned using appropriate photolithography and etch (e.g., RIE) processes.

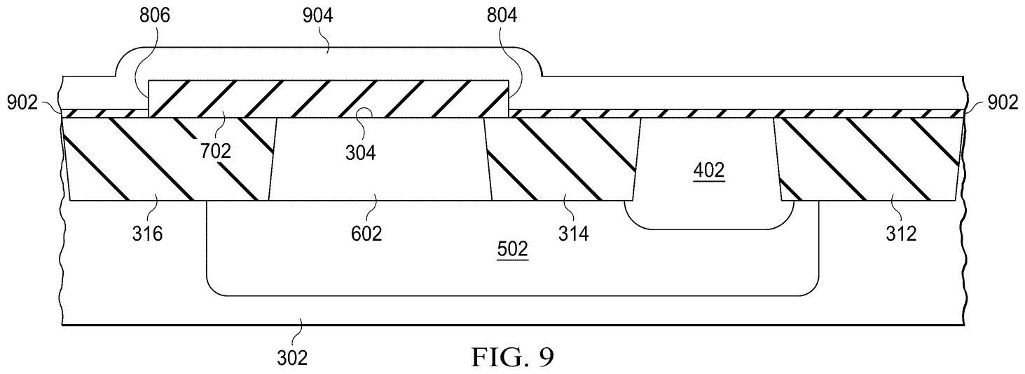

Referring to FIG. 9, an etch stop layer 902 is formed over the semiconductor substrate 302, and an extrinsic base layer 904 is formed over the etch stop layer 902 and the pedestal dielectric layer 702. The etch stop layer 902 may be or include any dielectric material that provides etch selectivity between the etch stop layer 902 and an overlying material or layer. In the illustrated example, the etch stop layer 902 is silicon oxide, which is formed by an oxidation process, such as in situ steam generation (ISSG) oxidation. In other examples, the etch stop layer 902 may be or include other materials, such as silicon nitride, and/or may be conformally deposited over the semiconductor substrate 302 and the pedestal dielectric layer 702, such as by CVD, atomic layer deposition (ALD), or the like.

The extrinsic base layer 904 may be or include a semiconductor material. In some examples, the extrinsic base layer 904 is or includes polycrystalline silicon (polysilicon). The extrinsic base layer 904 may be formed by a conformal deposition, such as by PECVD, another CVD, or the like. The extrinsic base layer 904 may be n-type doped. In some examples, the extrinsic base layer 904 may be in situ doped with an n-type dopant during deposition and/or may be implanted with an n-type dopant after deposition. In some examples, the extrinsic base layer 904 is doped with an n-type dopant with a concentration in a range from 1×10¹⁹ cm⁻³ to 1×10²⁰ cm⁻³. Other doping concentrations may be implemented.

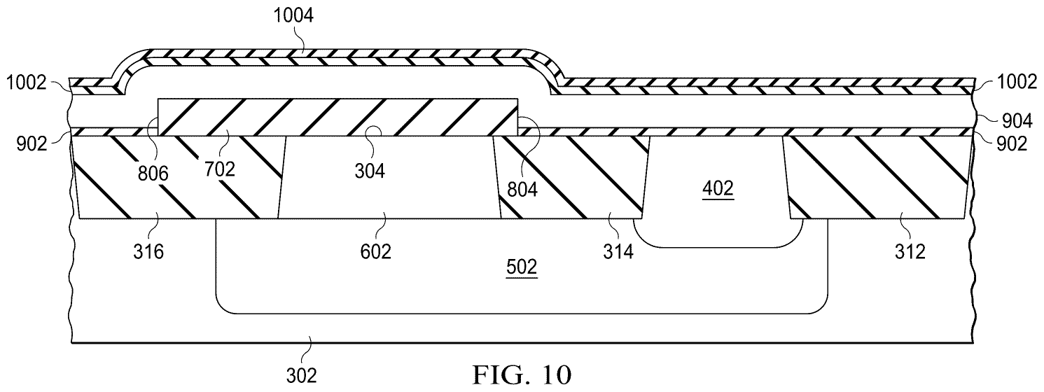

Referring to FIG. 10, a first vertical dielectric spacer layer 1002 is formed conformally over the extrinsic base layer 904, and a second vertical dielectric spacer layer 1004 is formed conformally over the first vertical dielectric spacer layer 1002. In some examples, the second vertical dielectric spacer layer 1004 is a dielectric material different from the dielectric material of the first vertical dielectric spacer layer 1002. In some examples, the first vertical dielectric spacer layer 1002 is silicon oxide (e.g., a TEOS oxide), and the second vertical dielectric spacer layer 1004 is silicon nitride. The vertical dielectric spacer layers 1002, 1004 may be deposited by CVD. Other dielectric materials and/or other deposition processes may be used in other examples.

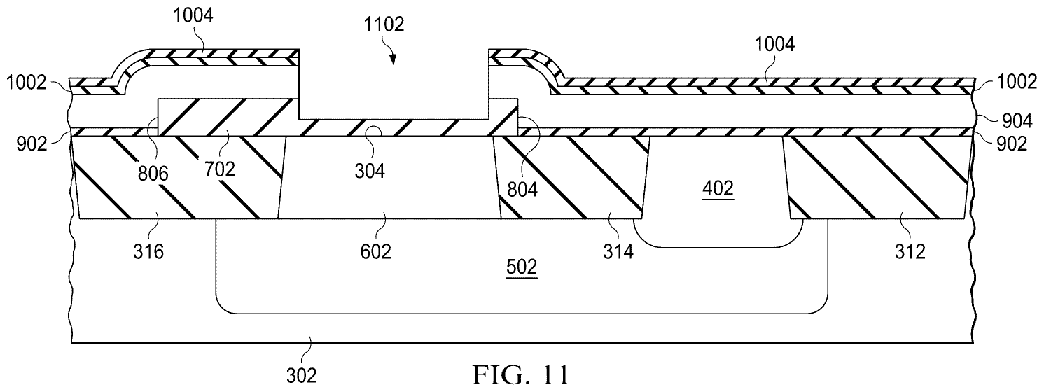

Referring to FIG. 11, an opening 1102 is formed through the first vertical dielectric spacer layer 1002, the second vertical dielectric spacer layer 1004, and the extrinsic base layer 904 and recessed into the pedestal dielectric layer 702. The opening 1102 is vertically over the second p-type sub-collector diffusion well 602 in the semiconductor substrate 302. The opening 1102 may be formed using appropriate photolithography and etch (e.g., RIE) processes.

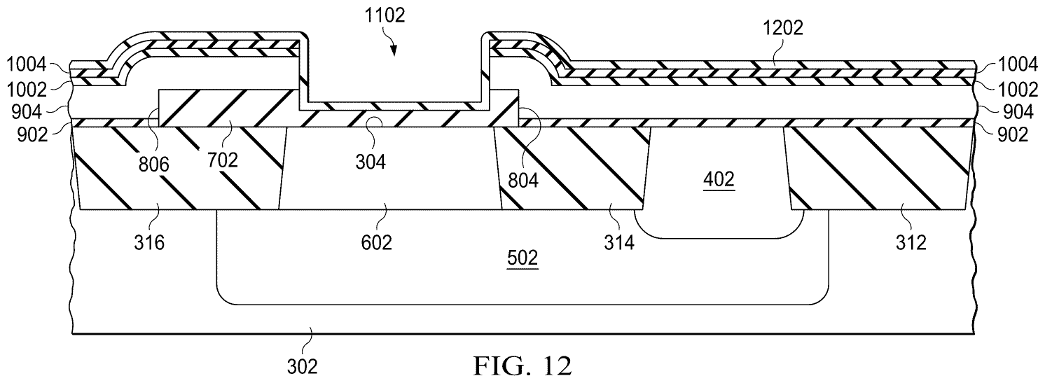

Referring to FIG. 12, a first horizontal dielectric spacer layer 1202 is formed conformally over the second vertical dielectric spacer layer 1004 and in the opening 1102 (e.g., along sidewalls of the vertical dielectric spacer layers 1002, 1004, extrinsic base layer 904, and pedestal dielectric layer 702 and on an upper surface of the pedestal dielectric layer 702 that defines the opening 1102). In some examples, the first horizontal dielectric spacer layer 1202 is silicon nitride. The first horizontal dielectric spacer layer 1202 may be deposited by CVD. Other dielectric materials and/or other deposition processes may be used in other examples.

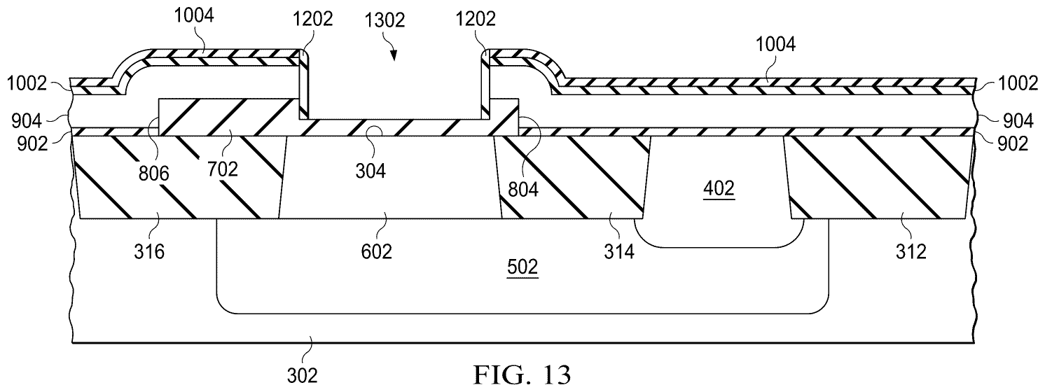

Referring to FIG. 13, the first horizontal dielectric spacer layer 1202 is anisotropically etched to form first horizontal dielectric spacers 1202 along sidewalls of the opening 1102 (e.g., on sidewalls of the vertical dielectric spacer layers 1002, 1004, the extrinsic base layer 904, and the pedestal dielectric layer 702 that define the opening 1102). The first horizontal dielectric spacers 1202 and exposed upper surface of the pedestal dielectric layer 702 define an opening 1302. The anisotropic etch may be any appropriate anisotropic etch process, such as an RIE.

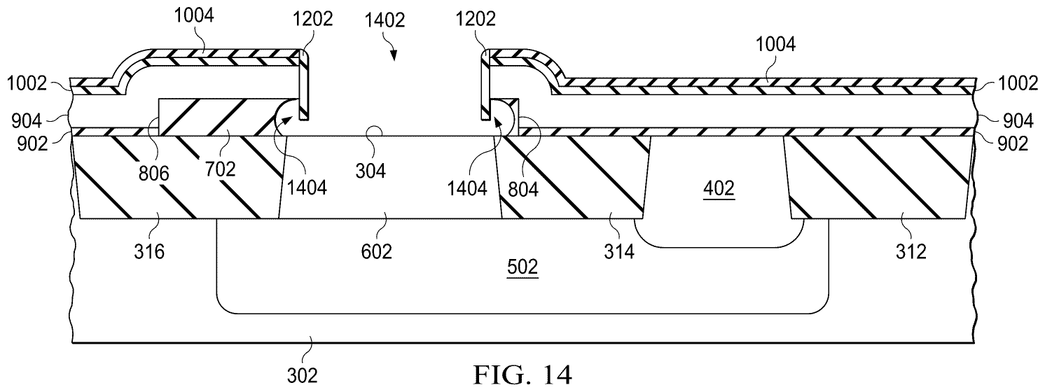

Referring to FIG. 14, the pedestal dielectric layer 702 is isotropically etched through the opening 1302 to form a base/emitter opening 1402. The isotropic etch removes the pedestal dielectric layer 702 from the bottom surface of the opening 1302 (e.g., from a surface of the pedestal dielectric layer 702) to the upper surface 304 of the semiconductor substrate 302 to expose the second p-type sub-collector diffusion well 602 in the semiconductor substrate 302. The isotropic etch further laterally etches the pedestal dielectric layer 702 to undercut the first horizontal dielectric spacers 1202 that are on the sidewalls that define the opening 1102. Undercutting the first horizontal dielectric spacers 1202 forms undercut portions 1404 of the base/emitter opening 1402. The pedestal dielectric layer 702 is etched in the undercut portions 1404 to expose portions of respective lower surfaces of the extrinsic base layer 904 by the undercut portions 1404. The isotropic etch process may be any appropriate etch process, such as a wet etch, which may include dilute hydrofluoric (dHF) acid or a buffered oxide etch (BOE) when the pedestal dielectric layer 702 is silicon oxide.

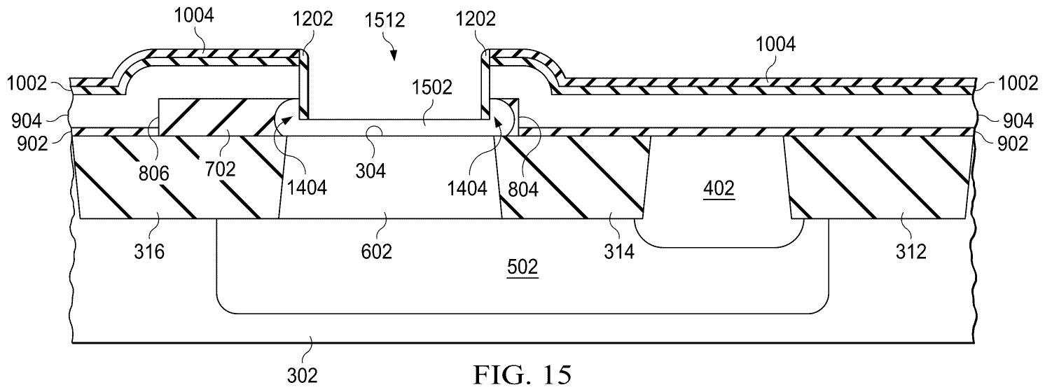

Referring to FIG. 15, a base layer 1502 is formed on and over the second p-type sub-collector diffusion well 602 in the semiconductor substrate 302 and in the base/emitter opening 1402. The base layer 1502 contacts the lower surfaces of the extrinsic base layer 904 through the undercut portions 1404 of the base/emitter opening 1402. An upper surface of the base layer 1502 defines a bottom surface of an opening 1512, which is formed by the base layer 1502 partially filling the base/emitter opening 1402. The opening 1512 is further defined by the first horizontal dielectric spacers 1202.

In some examples, the base layer 1502 is or includes a semiconductor layer doped with an n-type dopant (e.g., an opposite dopant type as the second p-type sub-collector diffusion well 602). In some examples, the base layer 1502 includes multiple sub-layers. For example, the base layer 1502 may include a first sub-layer over the semiconductor substrate 302, a second sub-layer over the first sub-layer, a third sub-layer over the second sub-layer, a fourth sub-layer over the third sub-layer, and a fifth sub-layer over the fourth sub-layer. The first sub-layer may be or include silicon germanium p-type doped with a p-type dopant. The second and fourth sub-layers may be or include silicon germanium. The third sub-layer may be or include silicon germanium n-type doped with an n-type dopant. An atomic concentration of germanium in the silicon germanium of the third sub-layer may be less than respective atomic concentrations of germanium in the silicon germanium of the second and fourth sub-layers. The fifth sub-layer may be or include a same material as an emitter layer (formed subsequently), such as silicon. In some examples, the second and third sub-layers may include carbon to reduce diffusion of a p-type dopant. In some examples, the base layer 1502 is doped with an n-type dopant with a concentration in a range from 5×10¹⁸ cm⁻³ to 5×10¹⁹ cm⁻³. The base layer 1502 may be epitaxially grown on the semiconductor substrate 302. The base layer 1502 may be epitaxially grown by a selective epitaxial growth process in some examples. The base layer 1502 (e.g., one or more sub-layers) may be in situ doped during the epitaxial growth process. The epitaxial growth process may be a CVD process, such as LPCVD, RPCVD, MOCVD, or the like. Other materials, dopant type, dopant concentration, and/or deposition process may be implemented.

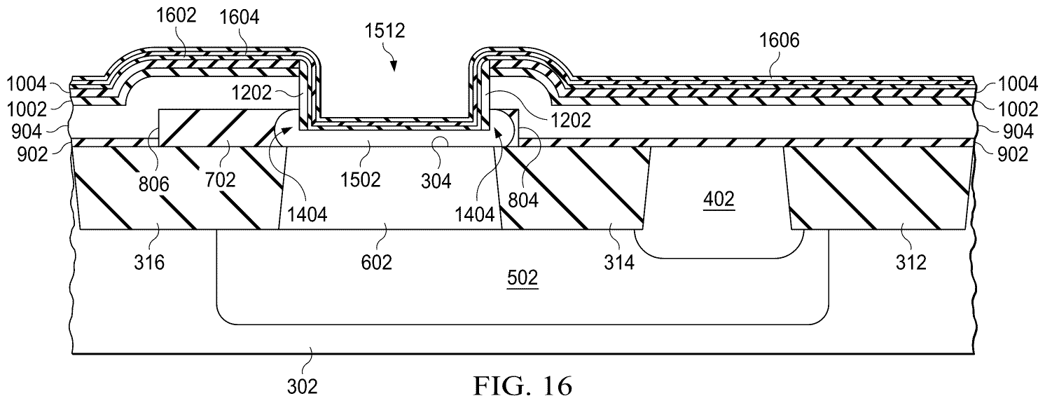

Referring to FIG. 16, a second horizontal dielectric spacer layer 1602 is formed conformally over the second vertical dielectric spacer layer 1004 and in the opening 1512 (e.g., along the first horizontal dielectric spacers 1202 and over and on the upper surface of the base layer 1502 that define the opening 1512). A third horizontal dielectric spacer layer 1604 is formed conformally over the second horizontal dielectric spacer layer 1602, and a fourth horizontal dielectric spacer layer 1606 is formed conformally over the third horizontal dielectric spacer layer 1604. In some examples, the second horizontal dielectric spacer layer 1602 and fourth horizontal dielectric spacer layer 1606 are a same dielectric material, and the third horizontal dielectric spacer layer 1604 is a dielectric material different from the dielectric material of the second horizontal dielectric spacer layer 1602 and fourth horizontal dielectric spacer layer 1606. In some examples, the second horizontal dielectric spacer layer 1602 and fourth horizontal dielectric spacer layer 1606 are silicon oxide (e.g., a TEOS oxide), and the third horizontal dielectric spacer layer 1604 is silicon nitride. The horizontal dielectric spacer layers 1602-1606 may be deposited by CVD. Other dielectric materials and/or other deposition processes may be used in other examples.

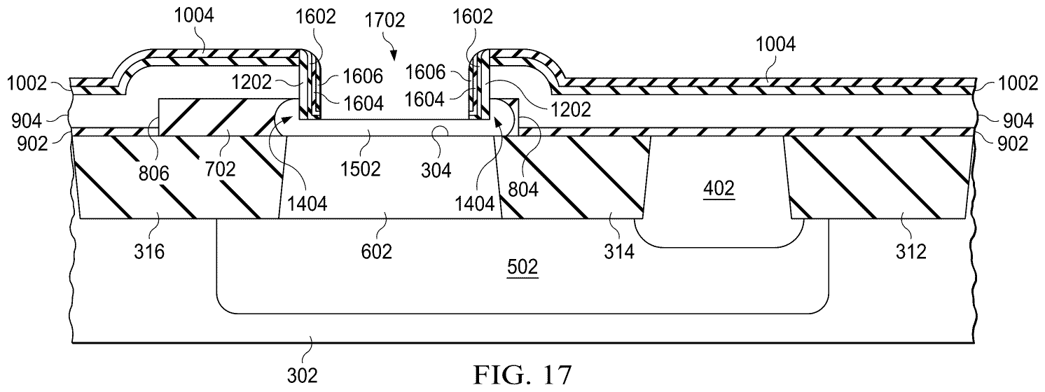

Referring to FIG. 17, the horizontal dielectric spacer layers 1602-1606 are anisotropically etched to form second horizontal dielectric spacers 1602, third horizontal dielectric spacers 1604, and fourth horizontal dielectric spacers 1606 on the first horizontal dielectric spacers 1202. The fourth horizontal dielectric spacers 1606 laterally define an emitter opening 1702. The base layer 1502 is exposed through the emitter opening 1702 and by the anisotropic etch. The horizontal dielectric spacer layers 1602-1606 may be etched using any appropriate anisotropic etch process, such as an RIE.

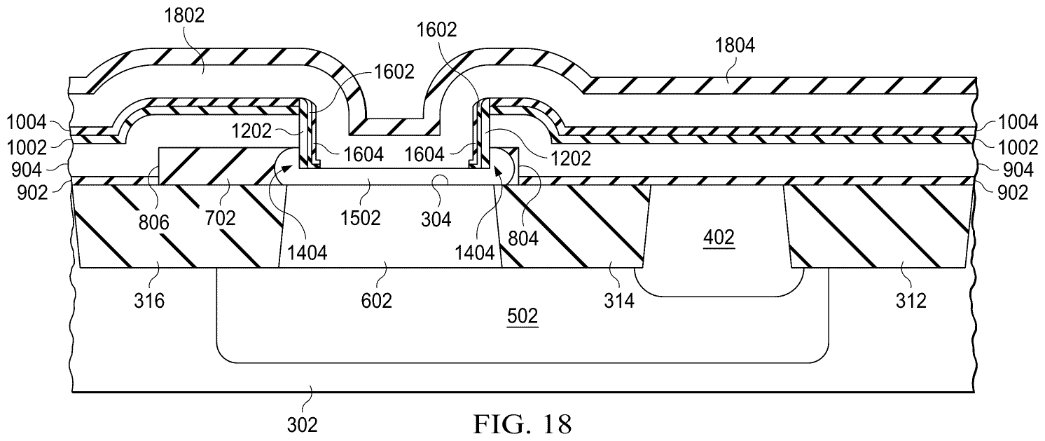

Referring to FIG. 18, an emitter layer 1802 is formed conformally over the second vertical dielectric spacer layer 1004 and in the emitter opening 1702 (e.g., over and on the upper surface of the base layer 1502 that partially defines the emitter opening 1702). The emitter layer 1802 may include a monocrystalline emitter layer portion and a polycrystalline emitter layer portion. For example, the monocrystalline emitter layer portion may be on the base layer 1502, and the polycrystalline emitter layer portion may be on a dielectric surface or other amorphous surface, such as the second vertical dielectric spacer layer 1004 and a horizontal dielectric spacer 1202, 1602-1606. The emitter layer 1802 includes a first emitter sub-layer and a second emitter sub-layer over the first emitter sub-layer, as described above with respect to FIGS. 1 and 2. The first and second emitter sub-layers are p-type doped with a p-type dopant (e.g., boron), and a concentration of the p-type dopant in the second emitter sub-layer is greater than a concentration of the p-type dopant in the first emitter sub-layer. In some examples, the first emitter sub-layer of the emitter layer 1802 is doped with a p-type dopant with a concentration in a range from 1×10¹⁹ cm⁻³ to 5×10²⁰ cm⁻³, and the second emitter sub-layer of the emitter layer 1802 is doped with a p-type dopant with a concentration equal to or greater than 5×10²⁰ cm⁻³ (e.g., equal to or greater than 1×10²¹ cm⁻³).

The emitter layer 1802 may be formed by a non-selective epitaxial growth process in some examples. Prior to the non-selective epitaxial growth process, a cleaning process may be performed, which as illustrated, may remove an oxide like the fourth horizontal dielectric spacers 1606. The non-selective epitaxial growth process may grow the monocrystalline emitter layer portion from the base layer 1502 in the emitter opening 1702 and may grow the polycrystalline emitter layer portion on other amorphous or polycrystalline surfaces, such as the second vertical dielectric spacer layer 1004 and the third horizontal dielectric spacers 1604. The monocrystalline emitter layer portion may meet the polycrystalline emitter layer portion at a facet that is not specifically illustrated. The non-selective epitaxial growth of the emitter layer 1802 forms the emitter layer 1802 conformally. The epitaxial growth of the emitter layer 1802 is as described above with respect to FIGS. 1 and 2. Other materials, dopant type, dopant concentration, and/or deposition process may be implemented.

An emitter dielectric cap layer 1804 is conformally formed over the emitter layer 1802. In some examples, the emitter dielectric cap layer 1804 is silicon oxide (e.g., a TEOS oxide) deposited by CVD, although other dielectric materials and/or other deposition processes may be used in other examples.

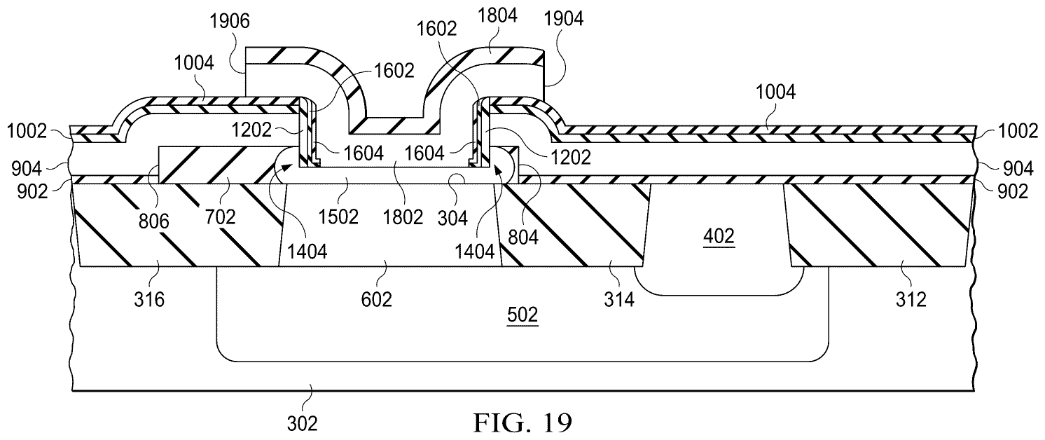

Referring to FIG. 19, the emitter dielectric cap layer 1804 and the emitter layer 1802 are patterned. The emitter layer 1802 is patterned to remain in the emitter opening 1702 and contacting the base layer 1502 and to remain extending laterally out of the emitter opening 1702 extending over the second vertical dielectric spacer layer 1004. The emitter layer 1802 is patterned to have a sidewall 1904 over the isolation structure 314 and to have a sidewall 1906 over the pedestal dielectric layer 702 and the isolation structure 316. The emitter dielectric cap layer 1804 is patterned to be laterally co-extensive with the emitter layer 1802. The emitter dielectric cap layer 1804 and the emitter layer 1802 are patterned using appropriate photolithography and etch (e.g., RIE) processes.

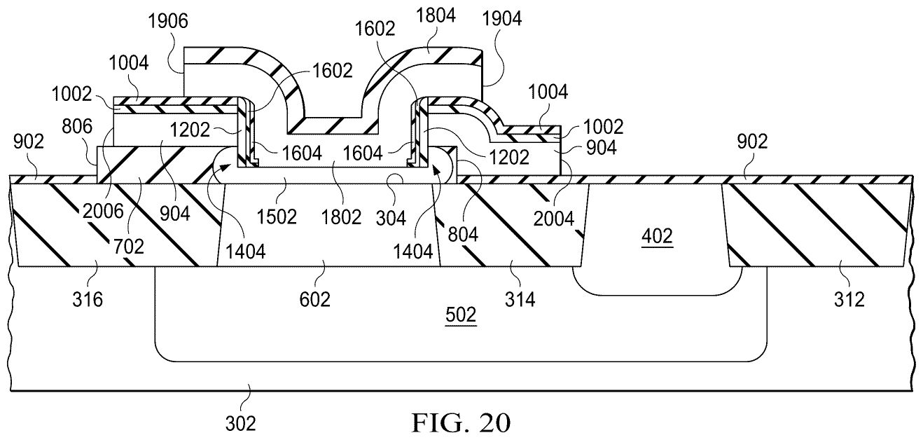

Referring to FIG. 20, the second vertical dielectric spacer layer 1004, the first vertical dielectric spacer layer 1002, and the extrinsic base layer 904 are patterned. The extrinsic base layer 904 is patterned to remain contacting the base layer 1502 and to remain extending laterally from the base layer 1502 over the pedestal dielectric layer 702 and isolation structures 314, 316. The extrinsic base layer 904 is patterned to have a sidewall 2004 over the isolation structure 314 and the etch stop layer 902 and to have a sidewall 2006 over the pedestal dielectric layer 702 and the isolation structure 316. The extrinsic base layer 904 extends laterally away from the sidewall 1904 of the emitter layer 1802 and extends laterally away from the sidewall 804 of the pedestal dielectric layer 702 to the sidewall 2004 of the extrinsic base layer 904. Laterally, the sidewall 1904 of the emitter layer 1802 is between the sidewall 804 of the pedestal dielectric layer 702 and the sidewall 2004 of the extrinsic base layer 904. The extrinsic base layer 904 extends laterally away from the sidewall 1906 of the emitter layer 1802 to the sidewall 2006 of the extrinsic base layer 904, and the pedestal dielectric layer 702 extends laterally away from the sidewall 2006 of the extrinsic base layer 904 to the sidewall 806 of the pedestal dielectric layer 702. Laterally, the sidewall 2006 of the extrinsic base layer 904 is between the sidewall 806 of the pedestal dielectric layer 702 and the sidewall 1906 of the emitter layer 1802. The vertical dielectric spacer layers 1002, 1004 are patterned to be laterally co-extensive with the extrinsic base layer 904. The extrinsic base layer 904 and the vertical dielectric spacer layers 1002, 1004 are patterned using appropriate photolithography and etch (e.g., RIE) processes.

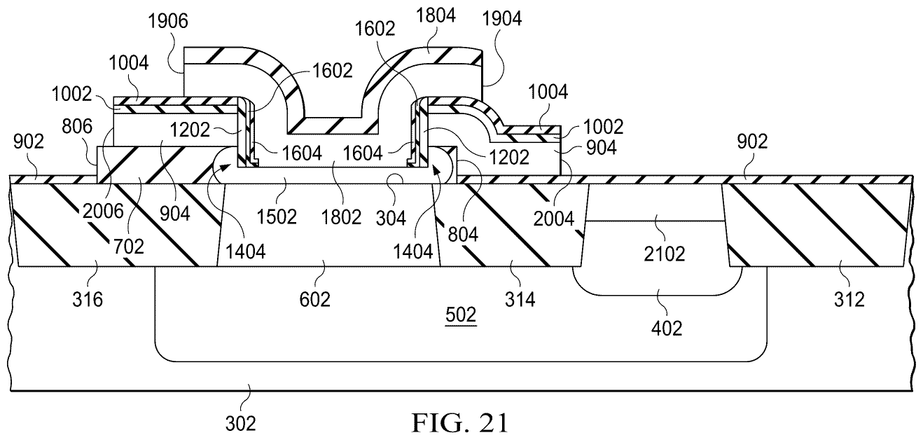

Referring to FIG. 21, a p-type collector contact region 2102 is formed in the semiconductor substrate 302. The p-type collector contact region 2102 is formed in the first p-type sub-collector diffusion well 402 in the semiconductor substrate 302. The p-type collector contact region 2102 is laterally between the isolation structures 312, 314. An implantation is performed to form the p-type collector contact region 2102. The p-type collector contact region 2102 may be formed by masking (e.g., by a photoresist using photolithography) the extrinsic base layer 904 and emitter layer 1802 and implanting a p-type dopant into the semiconductor substrate 302 in an exposed portion of the semiconductor substrate 302 corresponding to the p-type collector contact region 2102. A concentration of the p-type dopant of the p-type collector contact region 2102 is greater than the concentration of the p-type dopant of the first p-type sub-collector diffusion well 402. In some examples, the p-type collector contact region 2102 is doped with a p-type dopant with a concentration in a range from 1×10²⁰ cm⁻³ to 1×10²¹ cm⁻³. Other doping concentrations may be implemented.

In some examples, although not illustrated, n-type base contact regions may be formed in the extrinsic base layer 904. An implantation may be performed to form the n-type base contact regions. The n-type base contact regions may be formed by masking (e.g., by a photoresist using photolithography) the emitter layer 1802 and other areas of the semiconductor substrate 302 and implanting an n-type dopant into portions of the extrinsic base layer 904 that are not masked. In some examples, the n-type base contact regions may be doped with an n-type dopant with a concentration in a range from 1×10²⁰ cm⁻³ to 1×10²¹ cm⁻³. Other doping concentrations may be implemented.

Referring to FIG. 22, metal-semiconductor compound 2202, 2204, 2206 are formed. The metal-semiconductor compound 2202 is on the emitter layer 1802. The metal-semiconductor compound 2204 is on the extrinsic base layer 904. The metal-semiconductor compound 2206 is on the upper surface 304 of the semiconductor substrate 302 at the p-type collector contact region 2102. The metal-semiconductor compound 2202, 2204, 2206 may be a silicide (e.g., NiSix, TiSix, CoSix, PtSix), a germanicide, or the like.

To form the metal-semiconductor compound 2202, 2204, 2206, any remaining dielectric material on surfaces on which the metal-semiconductor compound 2202, 2204, 2206 are to be formed is removed. For example, exposed portions of the second vertical dielectric spacer layer 1004 (e.g., not underlying the emitter layer 1802) are removed, such as by an etch selective to the material of the second vertical dielectric spacer layer 1004. The second vertical dielectric spacer layer 1004 remains underlying the emitter layer 1802. Then, the emitter dielectric cap layer 1804, exposed portions of the first vertical dielectric spacer layer 1002 (e.g., not underlying the emitter layer 1802), and exposed portions of the etch stop layer 902 (e.g., not underlying the extrinsic base layer 904) are removed, such as by an etch selective to the materials of these layers. The first vertical dielectric spacer layer 1002 remains underlying the remaining second vertical dielectric spacer layer 1004 and the emitter layer 1802. Hence, the remaining vertical dielectric spacer layers 1002, 1004 have sidewalls that generally vertically align with the sidewalls 1904, 1906 of the emitter layer 1802. The etch stop layer 902 remains underlying the extrinsic base layer 904 laterally from the sidewall 804 of the pedestal dielectric layer 702 to the sidewall 2004 of the extrinsic base layer 904 and has a sidewall that generally vertically aligns with the sidewall 2004 of the extrinsic base layer 904. The removal of the emitter dielectric cap layer 1804 and exposed portions of the first vertical dielectric spacer layer 1002 and etch stop layer 902 may etch and reduce the thickness of an exposed portion of the pedestal dielectric layer 702, such as at the sidewall 806 of the pedestal dielectric layer 702.

The metal-semiconductor compound 2202, 2204, 2206 may then be formed by depositing a metal (e.g., Ni, Ti, Co, Pt) over the semiconductor substrate 302, such as by physical vapor deposition (PVD), CVD, or the like. The metal is reacted with a semiconductor material, such as the semiconductor material of the emitter layer 1802, the semiconductor material of the extrinsic base layer 904, and the semiconductor material of the semiconductor substrate 302. An anneal process may be used to cause the metal to react with a semiconductor material. For example, a laser anneal (e.g., a millisecond laser anneal) may be used in a reduced thermal budget implementation. Any unreacted metal may be removed, such as by an etch selective to the metal.

After forming the metal-semiconductor compound 2202, 2204, 2206, a dielectric layer 2212 is formed over the semiconductor substrate 302, and contacts 2222, 2224, 2226 are formed through the dielectric layer 2212. The dielectric layer 2212 may include one or more dielectric sub-layers. For example, the dielectric layer 2212 may include a conformal first dielectric sub-layer over the semiconductor substrate 302 and a second dielectric sub-layer over the first dielectric sub-layer. The conformal first dielectric sub-layer may be a stressor layer, an etch stop layer, or the like, which may be or include silicon nitride, silicon oxynitride, the like, or a combination thereof. The second dielectric sub-layer may be or include silicon oxide, silicon nitride, or the like. The dielectric layer 2212 may be or include a pre-metal dielectric (PMD), an inter-layer dielectric (ILD), or the like. The dielectric layer 2212 may be deposited using CVD, PECVD, ALD, or the like. The dielectric layer 2212 may be planarized, such as by a CMP.

The contacts 2222, 2224, 2226 extend through the dielectric layer 2212 and contact respective metal-semiconductor compound 2202, 2204, 2206. The contacts 2222, 2224, 2226 may each include one or more barrier and/or adhesion layers (e.g., titanium nitride (TiN), tantalum nitride (TaN), the like, or a combination thereof) conformally in a respective opening through the dielectric layer 2212, and a fill metal (e.g., tungsten (W), copper (Cu), aluminum (Al), the like, or a combination thereof) over and/or on the barrier and/or adhesion layer(s). To form the contacts 2222, 2224, 2226, respective openings may be formed through the dielectric layer 2212 to the metal-semiconductor compound 2202, 2204, 2206 using appropriate photolithography and etching processes. A metal(s) of the contacts 2222, 2224, 2226 are deposited in the openings through the dielectric layer 2212. The metal(s) may be deposited using an appropriate deposition process(es), such as CVD, PVD, or the like. Any excess metal(s) may be removed, such as by a CMP and/or by patterning using photolithography and etch processes.

FIG. 22 illustrates a semiconductor device 2200. The semiconductor device 2200 is or includes a BJT. The BJT includes a collector region (including the p-type sub-collector diffusion wells 402, 602 and the p-type buried layer 502), the base layer 1502, the extrinsic base layer 904, and the emitter layer 1802.

The collector region is in the semiconductor substrate 302. The collector region includes the second p-type sub-collector diffusion well 602 laterally between the isolation structures 314, 316, the first p-type sub-collector diffusion well 402 laterally between the isolation structures 312, 314, and the p-type buried layer 502 underlying the isolation structure 314 and extending from the second p-type sub-collector diffusion well 602 to the first p-type sub-collector diffusion well 402.

The base layer 1502 is over and on the upper surface 304 of the semiconductor substrate 302 at the second p-type sub-collector diffusion well 602 (e.g., is on the collector region). The base layer 1502 is through an opening in a pedestal dielectric layer 702, which is also over the upper surface 304 of the semiconductor substrate 302. The extrinsic base layer 904 is over the pedestal dielectric layer 702 and contacts the base layer 1502 at the opening through the pedestal dielectric layer 702. The emitter layer 1802 is over and on the base layer 1502 and extends laterally over the extrinsic base layer 904.

A spacer structure is between the extrinsic base layer 904 and the emitter layer 1802. The spacer structure includes one or more horizontal dielectric spacers (e.g., horizontal dielectric spacers 1202, 1602, 1604) along a sidewall of the extrinsic base layer 904 and laterally between the emitter layer 1802 and the extrinsic base layer 904. The spacer structure also includes one or more vertical dielectric spacer layers (e.g., vertical dielectric spacer layers 1002, 1004) along an upper surface of the extrinsic base layer 904 and vertically between the emitter layer 1802 and the extrinsic base layer 904. The opening through the pedestal dielectric layer 702 in which the base layer 1502 is disposed has undercut portions under the one or more horizontal dielectric spacers (e.g., horizontal dielectric spacers 1202, 1602, 1604) and laterally between the one or more horizontal dielectric spacers and the pedestal dielectric layer 702. The base layer 1502 contacts the extrinsic base layer 904 at the undercut portions of the opening through the pedestal dielectric layer 702.

The pedestal dielectric layer 702 underlies the extrinsic base layer 904. The pedestal dielectric layer 702 extends laterally from the base layer 1502. For example, the pedestal dielectric layer 702 extends over and on the isolation structure 314 laterally away from the base layer 1502 to the sidewall 804 of the pedestal dielectric layer 702, and the sidewall 804 overlies the isolation structure 314. Additionally, the pedestal dielectric layer 702 extends over and on the isolation structure 316 laterally away from the base layer 1502 to the sidewall 806 of the pedestal dielectric layer 702, and the sidewall 806 overlies the isolation structure 316. The extrinsic base layer 904 extends laterally away from the sidewall 804 of the pedestal dielectric layer 702 and over the etch stop layer 902 to a sidewall 2004 of the extrinsic base layer 904, which sidewall 2004 overlies the isolation structure 314. The extrinsic base layer 904 also has a sidewall 2006 over the pedestal dielectric layer 702, which sidewall 2006 also overlies the isolation structure 316.

In some examples, the BJT may be a heterojunction BJT. As indicated previously, in some examples, the collector region and the emitter layer 1802 may be silicon, and the base layer 1502 may include silicon germanium. Hence, in some examples, the base layer 1502 may include a semiconductor material dissimilar from respective semiconductor materials of the collector region and emitter layer 1802. The dissimilar semiconductor materials may form one or more heterojunctions in the BJT, and the BJT may therefore be a heterojunction BJT.

Although various examples have been described in detail, it should be understood that various changes, substitutions, and alterations can be made therein without departing from the scope defined by the appended claims.

What is claimed is:

1. A bipolar junction transistor, comprising:
a collector;
a base on the collector; and
an emitter layer on the base, the emitter layer comprising:
a first emitter sub-layer comprising boron and carbon, wherein a concentration of carbon is uniform throughout the first emitter sub-layer; and
a second emitter sub-layer over the first emitter sub-layer, the second emitter sub-layer comprising boron, wherein a concentration of boron in the second emitter sub-layer is greater than a concentration of boron in the first emitter sub-layer.

2. The bipolar junction transistor of claim 1, wherein:
the concentration of boron in the second emitter sub-layer is equal to or greater than 5×10²⁰ cm⁻³; and
the concentration of boron in the first emitter sub-layer is in a range from 1×10¹⁹ cm⁻³ to 5×10²⁰ cm⁻³.

3. The bipolar junction transistor of claim 1, wherein the concentration of boron in the second emitter sub-layer is equal to or greater than 1×10²¹ cm⁻³.

4. The bipolar junction transistor of claim 1, wherein the concentration of carbon corresponds to equal to or greater than 0.2 atomic % of the first emitter sub-layer.

5. The bipolar junction transistor of claim 1, wherein the second emitter sub-layer is exclusive of carbon.

6. The bipolar junction transistor of claim 1, wherein:
a thickness of the first emitter sub-layer is in a range from 15 nm to 50 nm; and
a thickness of the second emitter sub-layer is in a range from 15 nm to 100 nm.

7. The bipolar junction transistor of claim 1, wherein the first emitter sub-layer includes a monocrystalline semiconductor material.

8. A method, comprising:
forming a bipolar junction transistor including a collector, a base on the collector, and an emitter layer on the base, forming the bipolar junction transistor including forming the emitter layer, forming the emitter layer including:
forming a first emitter sub-layer; and
forming a second emitter sub-layer over the first emitter sub-layer, wherein forming the second emitter sub-layer includes in situ doping, at a first temperature, the second emitter sub-layer with boron to a concentration of boron equal to or greater than 5×10²⁰ cm⁻³, the first temperature being 475° C. or less.

9. The method of claim 8, wherein the concentration of boron in the second emitter sub-layer is equal to or greater than 1×10²¹ cm⁻³.

10. The method of claim 8, wherein:
forming the first emitter sub-layer includes epitaxially growing the first emitter sub-layer; and
forming the second emitter sub-layer includes epitaxially growing the second emitter sub-layer at the first temperature.

11. The method of claim 10, wherein:
epitaxially growing the first emitter sub-layer includes flowing a first gas mixture including nitrogen (N₂) gas, silane (SiH₄) gas, and diborane (B₂H₆) gas, and a carbon source gas; and
epitaxially growing the second emitter sub-layer includes flowing a second gas mixture including nitrogen (N₂) gas, silane (SiH₄) gas, and diborane (B₂H₆) gas.

12. The method of claim 11, wherein the second gas mixture does not include hydrogen (H₂) gas and does not include a gas including a chlorine atom.

13. The method of claim 11, wherein a concentration of the diborane (B₂H₆) gas in the second gas mixture is in a range from 3,000 parts per billion to 9,500 parts per billion.

14. The method of claim 11, wherein the carbon source gas includes monomethylsilane (MMS, CH₃SiH₃).

15. The method of claim 11, wherein:
in the first gas mixture:
a flow rate of the nitrogen (N₂) gas is in a range from 10 standard liter per minute (slm) to 15 slm;
a flow rate of the silane (SiH₄) gas is in a range from 150 standard cubic centimeter per minute (sccm) to 250 sccm;
a flow rate of the diborane (B₂H₆) gas that results in the diborane (B₂H₆) gas having a concentration in a range from 100 parts per billion (ppb) to 400 ppb in the first gas mixture; and
a flow rate of the carbon source gas is in a range from 10 sccm to 90 sccm; and
in the second gas mixture:
a flow rate of the nitrogen (N₂) gas is in a range from 10 slm to 15 slm;
a flow rate of the silane (SiH₄) gas is in a range from 100 sccm to 200 sccm; and
a flow rate of the diborane (B₂H₆) gas that results in the diborane (B₂H₆) gas having a concentration in a range from 3,000 ppb to 9,500 ppb in the second gas mixture.

16. The method of claim 10, wherein epitaxially growing the first emitter sub-layer is at a second temperature greater than the first temperature.

17. The method of claim 16, wherein the second temperature is 100° C. or more greater than the first temperature.

18. The method of claim 16, wherein the second emitter sub-layer includes a monocrystalline semiconductor material.

19. The method of claim 16, wherein:
the second temperature is in a range from 425° C. to 475° C.; and
the first temperature is in a range from 500° C. to 600° C.

20. The method of claim 8, wherein forming the first emitter sub-layer includes in situ doping the first emitter sub-layer with boron to a concentration of boron in a range from 1×10¹⁹ cm⁻³ to 5×10²⁰ cm⁻³.

21. The method of claim 8, wherein forming the first emitter sub-layer includes in situ doping the first emitter sub-layer with carbon to a concentration of carbon corresponding to equal to or greater than 0.2 atomic % of the first emitter sub-layer.

22. The method of claim 21, wherein the concentration of carbon is substantially uniform throughout the first emitter sub-layer.
